(19) United States
(12) Patent Application Publication
(10) Pub. No.: US 2023/0251207 A1
(43) Pub. Date: Aug. 10, 2023

(54) PATTERN INSPECTION APPARATUS AND PATTERN INSPECTION METHOD

(71) Applicant: NuFlare Technology, Inc., Yokohama-shi (JP)

(72) Inventor: Shinji SUGIHARA, Ota-Ku (JP)

(73) Assignee: NuFlare Technology, Inc., Yokohama-shi (JP)

(21) Appl. No.: 18/004,683

(22) PCT Filed: May 14, 2021
(86) PCT No.: PCT/JP2021/018379

§ 371 Date: Jan. 9, 2023

(30) Foreign Application Priority Data
Jul. 13, 2020 (JP) 2020-119715

(51) Int. Cl. G01N 21/956; G06T 7/00; G06T 7/13; G06V 10/74; G01B 11/16

(52) U.S. Cl. CPC G01N 21/95607; G06T 7/001; G06T 7/13; G06V 10/761; G01B 11/16; G06T 2207/30148

(57) ABSTRACT

A pattern inspection apparatus according to one aspect of the present invention includes an image acquisition mechanism configured to acquire an inspection image of a substrate on which a figure pattern is formed, a distortion coefficient calculation circuit configured to calculate, using a plurality of actual image outline positions on an actual image outline of the figure pattern in the inspection image and a plurality of reference outline positions on a reference outline to be compared with the actual image outline, distortion coefficients by performing weighting in a predetermined direction at each actual image outline position of the plurality of actual image outline positions caused by distortion of the inspection image, a distortion vector estimation circuit configured to estimate, for each actual image outline position of the plurality of actual image outline positions, a distortion vector by using the distortion coefficients, and a comparison circuit configured to compare, using the distortion vector at each actual image outline position, the actual image outline with the reference outline.

### TECHNICAL FIELD

This application is based upon and claims the benefit of priority from Japanese Patent Application No. 2020-119715 filed on Jul. 13, 2020 in Japan, the contents of which are incorporated herein.

One aspect of the present invention relates to a pattern inspection apparatus and a pattern inspection method. For example, it relates to an inspection apparatus that performs inspection using a secondary electron image of a pattern emitted from the substrate irradiated with multiple electron beams, an inspection apparatus that performs inspection using an optical image of a pattern acquired from the substrate irradiated with ultraviolet rays, and a method therefor.

### BACKGROUND ART

In recent years, with advances in high integration and large capacity of the LSI (Large Scale Integrated circuits), the circuit line width required for semiconductor elements is becoming increasingly narrower. Because the LSI manufacturing requires an enormous production cost, it is essential to improve the yield. However, since patterns that make up the LSI have reached the order of 10 nanometers or less, dimensions to be detected as a pattern defect have become extremely small. Therefore, the pattern inspection apparatus for inspecting defects of ultrafine patterns exposed/transferred onto a semiconductor wafer needs to be highly accurate. Further, one of major factors that decrease the yield is due to pattern defects on the mask used for exposing/transferring ultrafine patterns onto a semiconductor wafer by the photolithography technology. Accordingly, the pattern inspection apparatus for inspecting defects on an exposure transfer mask used in manufacturing LSI needs to be highly accurate.

As a defect inspection method, there is known a method of comparing a measured image acquired by imaging a pattern formed on a substrate, such as a semiconductor wafer or a lithography mask, with design data or with another measured image acquired by imaging an identical pattern on the substrate. For example, as a pattern inspection method, there are “die-to-die inspection” and “die-to-database inspection”. The “die-to-die inspection” method compares data of measured images acquired by imaging identical patterns at different positions on the same substrate. The “die-to-database inspection” method generates, based on design data of a pattern, design image data (reference image), and compares it with a measured image being measured data acquired by imaging the pattern. Acquired images are transmitted as measured data to a comparison circuit. After performing an alignment between the images, the comparison circuit compares the measured data with reference data according to an appropriate algorithm, and determines that there is a pattern defect if the compared data do not match each other.

With respect to the pattern inspection apparatus described above, in addition to the apparatus that irradiates an inspection target substrate with laser beams in order to obtain a transmission image or a reflection image, there has been developed another inspection apparatus that acquires a pattern image by scanning an inspection target substrate with primary electron beams and detecting secondary electrons emitted from the inspection target substrate due to the irradiation with the primary electron beams. For such pattern inspection apparatus, it has been examined, instead of comparing pixel values, to extract an outline contour line of a pattern in an image, and use the distance between the extracted outline and the outline of a reference image, as a determining index. As for deviation between outlines, there is a positional deviation due to distortion of an image itself in addition to a positional deviation due to defects. Therefore, in order to accurately inspect whether a defect exists in outlines, it is necessary to perform an alignment with high precision between an outline of an inspection image and a reference outline, for correcting a deviation due to distortion of a measured image itself. However, alignment processing between outlines is complicated compared with conventional alignment processing between images which minimizes a deviation in a luminance value of each pixel by a least squares method, and thus, there is a problem that the processing takes a long time to perform a high-precision alignment.

The following method has been disclosed as a method for extracting an outline position on an outline, which is performed before alignment processing. In the disclosed method, edge candidates are obtained using a Sobel filter, etc., and then, a second differential value of a concentration value is calculated for each pixel of the edge candidates and adjacent pixels in the inspection region. Further, in two pixel groups adjacent to the edge candidates, one of the adjacent pixel groups which has more number of combinations of different signs of second differential values is selected as a second edge candidates. Then, using the second differential value of the edge candidate and that of the second edge candidate, edge coordinates of a detection target edge are obtained for each sub-pixel (e.g., refer to Patent Literature 1).

### CITATION LIST

### Patent Literature

Patent Literature 1: JP-A-2011-48592

SUMMARY OF INVENTION

### Technical Problem

One aspect of the present invention provides an apparatus and method capable of performing inspection according to a positional deviation due to distortion of a measured image.

### Solution to Problem

According to one aspect of the present invention, a pattern inspection apparatus includes
an image acquisition mechanism configured to acquire an inspection image of a substrate on which a figure pattern is formed;
a distortion coefficient calculation circuit configured to calculate, using a plurality of actual image outline positions on an actual image outline of the figure pattern in the inspection image and a plurality of reference outline positions on a reference outline to be compared with the actual image outline, distortion coefficients by performing weighting in a predetermined direction at each actual image outline position of the plurality of actual image outline positions caused by distortion of the inspection image;
a distortion vector estimation circuit configured to estimate, for the each actual image outline position of the plurality of actual image outline positions, a distortion vector by using the distortion coefficients; and
a comparison circuit configured to compare, using the distortion vector at the each actual image outline position, the actual image outline with the reference outline.

According to another aspect of the present invention, a pattern inspection apparatus includes
an image acquisition mechanism configured to acquire an inspection image of a substrate on which a figure pattern is formed;
an average shift vector calculation circuit configured to calculate, using a plurality of actual image outline positions on an actual image outline of the figure pattern in the inspection image and a plurality of reference outline positions to be compared with the plurality of actual image outline positions, an average shift vector weighted in a predetermined direction with respect to the actual image outline for performing, by a parallel shift, an alignment between the plurality of actual image outline positions and the plurality of reference outline positions; and
a comparison circuit configured to compare, using the average shift vector, the actual image outline with a reference outline.

According to yet another aspect of the present invention, a pattern inspection method includes
acquiring an inspection image of a substrate on which a figure pattern is formed;
calculating, using a plurality of actual image outline positions on an actual image outline of the figure pattern in the inspection image and a plurality of reference outline positions on a reference outline to be compared with the actual image outline, distortion coefficients by performing weighting in a predetermined direction at each actual image outline position of the plurality of actual image outline positions caused by distortion of the inspection image;
estimating, for the each actual image outline position of the plurality of actual image outline positions, a distortion vector by using the distortion coefficients; and
comparing, using the distortion vector at the each actual image outline position, the actual image outline with the reference outline, and outputting a result.

According to yet another aspect of the present invention, a pattern inspection method includes
acquiring an inspection image of a substrate on which a figure pattern is formed;
calculating, using a plurality of actual image outline positions on an actual image outline of the figure pattern in the inspection image and a plurality of reference outline positions to be compared with the plurality of actual image outline positions, an average shift vector weighted in a predetermined direction with respect to the actual image outline for performing, by a parallel shift, an alignment between the plurality of actual image outline positions and the plurality of reference outline positions; and
comparing, using the average shift vector, the actual image outline with a reference outline, and outputting a result.

### Advantageous Effects of Invention

According to one aspect of the present invention, it is possible to perform inspection according to a positional deviation due to distortion of a measured image.

### BRIEF DESCRIPTION OF DRAWINGS

FIG. 1 is a diagram showing an example of a configuration of a pattern inspection apparatus according to an embodiment 1.

FIG. 2 is a conceptual diagram showing a configuration of a shaping aperture array substrate according to the embodiment 1.

FIG. 3 is an illustration of an example of a plurality of chip regions formed on a semiconductor substrate, according to the embodiment 1.

FIG. 4 is an illustration of a scanning operation with multiple beams according to the embodiment 1.

FIG. 5 is a flowchart showing main steps of an inspection method according to the embodiment 1.

FIG. 6 is a block diagram showing an example of a configuration in a comparison circuit according to the embodiment 1.

FIG. 7 is a diagram showing an example of an actual image outline position according to the embodiment 1.

FIG. 8 is a diagram for explaining an example of a method for extracting a reference outline position according to the embodiment 1.

FIG. 9 is a diagram showing an example of an individual shift vector according to the embodiment 1.

FIG. 10 is a diagram for explaining a method of calculating a weighted average shift vector according to the embodiment 1.

FIG. 11 is an illustration for explaining a defective positional deviation vector according to an average shift vector according to the embodiment 1.

FIG. 12 is a diagram for explaining a two-dimensional distortion model according to the embodiment 1.

FIG. 13 is an illustration for explaining a defective positional deviation vector according to a distortion vector according to the embodiment 1.

FIG. 14 is a diagram showing an example of a measurement result of a positional deviation amount of an image to which a distortion is added, and a positional deviation amount for which distortion is estimated without performing weighting in a normal direction according to the embodiment 1.

FIG. 15 is a diagram showing an example of a measurement result of a positional deviation amount of an image to which a distortion is added, and a positional deviation amount for which distortion is estimated with performing weighting in a normal direction according to the embodiment 1.

### DESCRIPTION OF EMBODIMENTS

### Embodiment 1

The embodiments below describe an electron beam inspection apparatus as an example of a pattern inspection apparatus. However, it is not limited thereto. For example, the inspection apparatus may be the one in which the inspection substrate, to be inspected, is irradiated with ultraviolet rays to obtain an inspection image using a light transmitted through the inspection substrate or reflected therefrom. Further, embodiments below describe an inspection apparatus using multiple electron beams to acquire an image, but it is not limited thereto. The inspection apparatus using a single electron beam to acquire an image may also be employed.

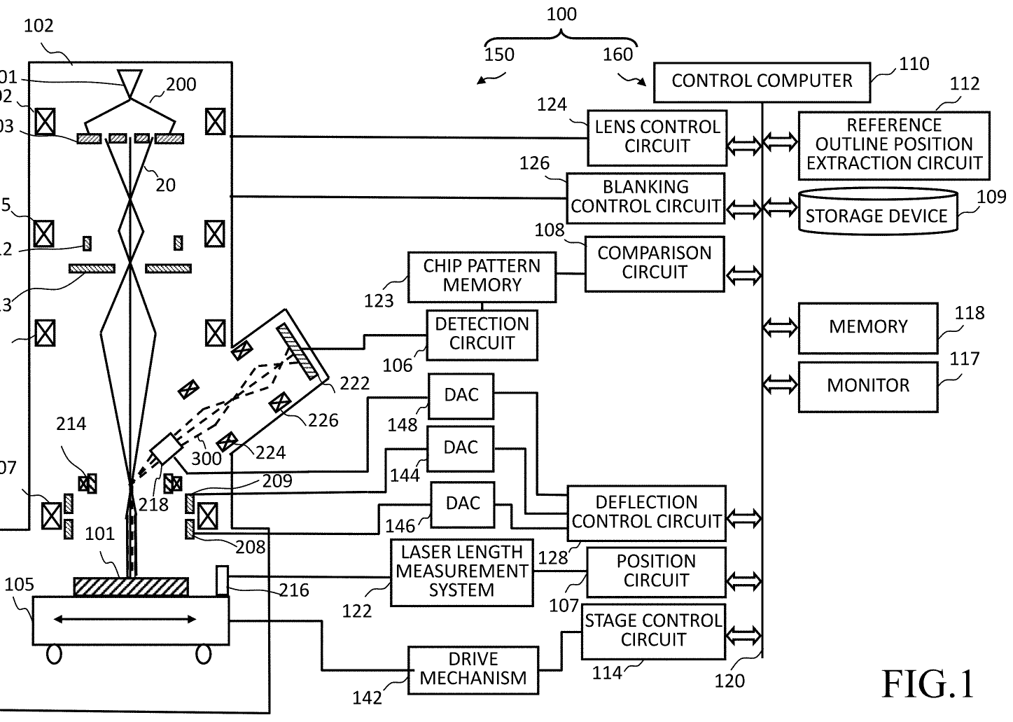

FIG. 1 is a diagram showing an example of a configuration of a pattern inspection apparatus according to an embodiment 1. In FIG. 1, an inspection apparatus 100 for inspecting a pattern formed on the substrate is an example of a multi-electron beam inspection apparatus. The inspection apparatus 100 includes an image acquisition mechanism 150 (secondary electron image acquisition mechanism) and a control system circuit 160. The image acquisition mechanism 150 includes an electron beam column 102 (electron optical column) and an inspection chamber 103. In the electron beam column 102, there are disposed an electron gun 201, an electromagnetic lens 202, a shaping aperture array substrate 203, an electromagnetic lens 205, a collective blanking deflector 212, a limiting aperture substrate 213, an electromagnetic lens 206, an electromagnetic lens 207 (objective lens), a main deflector 208, a sub deflector 209, an E×B separator 214 (beam separator), a deflector 218, an electromagnetic lens 224, an electromagnetic lens 226, and a multi-detector 222. In the case of FIG. 1, a primary electron optical system which irradiates a substrate 101 with multiple primary electron beams is composed of the electron gun 201, the electromagnetic lens 202, the shaping aperture array substrate 203, the electromagnetic lens 205, the collective blanking deflector 212, the limiting aperture substrate 213, the electromagnetic lens 206, the electromagnetic lens 207 (objective lens), the main deflector 208, and the sub deflector 209. A secondary electron optical system which irradiates the multi-detector 222 with multiple secondary electron beams is composed of the E×B separator 214, the deflector 218, the electromagnetic lens 224, and the electromagnetic lens 226.

In the inspection chamber 103, there is disposed a stage 105 movable at least in the x and y directions. The substrate 101 (target object) to be inspected is mounted on the stage 105. The substrate 101 may be an exposure mask substrate, or a semiconductor substrate such as a silicon wafer. In the case of the substrate 101 being a semiconductor substrate, a plurality of chip patterns (wafer dies) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed/transferred onto the semiconductor substrate a plurality of times, a plurality of chip patterns (wafer dies) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from a laser length measuring system 122 arranged outside the inspection chamber 103. The multi-detector 222 is connected, at the outside of the electron beam column 102, to a detection circuit 106.

In the control system circuit 160, a control computer 110 which controls the whole of the inspection apparatus 100 is connected, through a bus 120, to a position circuit 107, a comparison circuit 108, a reference outline position extraction circuit 112, a stage control circuit 114, a lens control circuit 124, a blanking control circuit 126, a deflection control circuit 128, a storage device 109 such as a magnetic disk drive, a monitor 117, and a memory 118. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The detection circuit 106 is connected to a chip pattern memory 123 which is connected to the comparison circuit 108. The stage 105 is driven by a drive mechanism 142 under the control of the stage control circuit 114. In the drive mechanism 142, a drive system such as a three (x-, y-, and θ-) axis motor which provides drive in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measuring system 122, and supplied to the position circuit 107. Based on the principle of laser interferometry, the laser length measuring system 122 measures the position of the stage 105 by receiving a reflected light from the mirror 216. In the stage coordinate system, the x, y, and θ directions are set, for example, with respect to a plane perpendicular to the optical axis (center axis of electron trajectory) of the multiple primary electron beams.

The electromagnetic lenses 202, 205, 206, 207 (objective lens), 224 and 226, and the E×B separator 214 are controlled by the lens control circuit 124. The collective blanking deflector 212 is composed of two or more electrodes, and each electrode is controlled by the blanking control circuit 126 through a DAC amplifier (not shown). The sub deflector 209 is composed of four or more electrodes, and each electrode is controlled by the deflection control circuit 128 through the DAC amplifier 144. The main deflector 208 is composed of four or more electrodes, and each electrode is controlled by the deflection control circuit 128 through the DAC amplifier 146. The deflector 218 is composed of four or more electrodes, and each electrode is controlled by the deflection control circuit 128 through the DAC amplifier 148.

To the electron gun 201, there is connected a high voltage power supply circuit (not shown). The high voltage power supply circuit applies an acceleration voltage between a filament (cathode) and an extraction electrode (anode) (which are not shown) in the electron gun 201. In addition to the applying the acceleration voltage, a voltage is applied to another extraction electrode (Wehnelt), and the cathode is heated to a predetermined temperature, and thereby, electrons from the cathode are accelerated to be emitted as an electron beam 200.

FIG. 1 shows configuration elements necessary for describing the embodiment 1. Other configuration elements generally necessary for the inspection apparatus 100 may also be included therein.

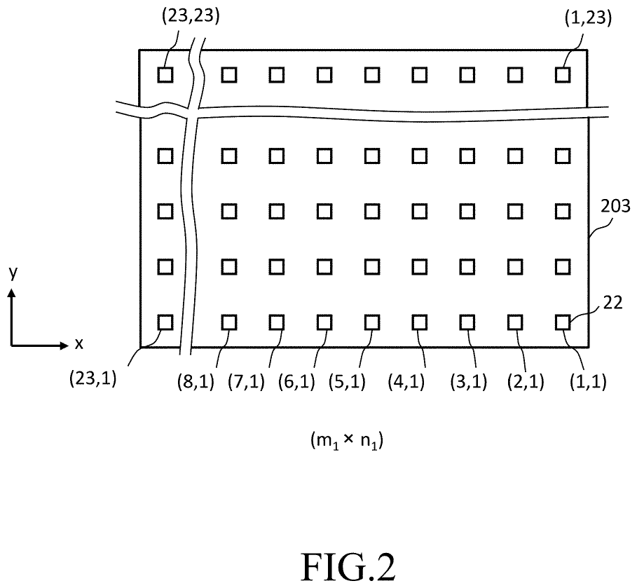

FIG. 2 is a conceptual diagram showing a configuration of a shaping aperture array substrate according to the embodiment 1. As shown in FIG. 2, holes (openings) 22 of m₁ columns wide (width in the x direction) and n₁ rows long (length in the y direction) are two-dimensionally formed at a predetermined arrangement pitch in the shaping aperture array substrate 203, where one of m₁ and n₁ is an integer of 2 or more, and the other is an integer of 1 or more. In the case of FIG. 2, 23×23 holes (openings) 22 are formed. Ideally, each of the holes 22 is a rectangle having the same dimension and shape. Alternatively, ideally, each of the holes 22 may be a circle with the same outer diameter. m₁×n₁ (=N) multiple primary electron beams 20 are formed by letting portions of the electron beam 200 individually pass through a plurality of holes 22.

Next, operations of the image acquisition mechanism 150 in the inspection apparatus 100 will be described below.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all the plurality of holes 22 is irradiated by the electron beam 200. The multiple primary electron beams 20 are formed by letting portions of the electron beam 200 applied to the positions of the plurality of holes 22 individually pass through the plurality of holes 22 in the shaping aperture array substrate 203.

The formed multiple primary electron beams 20 are individually refracted by the electromagnetic lenses 205 and 206, and travel to the electromagnetic lens 207 (objective lens), while repeating forming an intermediate image and a crossover, passing through the E×B separator 214 disposed at the crossover position of each beam (at the intermediate image position of each beam) of the multiple primary electron beams 20. Then, the electromagnetic lens 207 focuses the multiple primary electron beams 20 onto the substrate 101. The multiple primary electron beams 20 having been focused on the substrate 101 (target object) by the objective lens 207 are collectively deflected by the main deflector 208 and the sub deflector 209 to irradiate respective beam irradiation positions on the substrate 101. When all of the multiple primary electron beams 20 are collectively deflected by the collective blanking deflector 212, they deviate from the hole in the center of the limiting aperture substrate 213 and are blocked by the limiting aperture substrate 213. By contrast, the multiple primary electron beams 20 which were not deflected by the collective blanking deflector 212 pass through the hole in the center of the limiting aperture substrate 213 as shown in FIG. 1. Blanking control is provided by On/Off of the collective blanking deflector 212, and thus On/Off of beams is collectively controlled. In this way, the limiting aperture substrate 213 blocks the multiple primary electron beams 20 which were deflected to be in the “Off condition” by the collective blanking deflector 212. Then, the multiple primary electron beams 20 for inspection (for image acquisition) are formed by the beams having been made during from becoming “beam On” to becoming “beam Off” and having passed through the limiting aperture substrate 213.

When desired positions on the substrate 101 are irradiated with the multiple primary electron beams 20, a flux of secondary electrons (multiple secondary electron beams 300) including reflected electrons, each corresponding to each of the multiple primary electron beams 20, is emitted from the substrate 101 due to the irradiation with the multiple primary electron beams 20.

The multiple secondary electron beams 300 emitted from the substrate 101 travel to the E×B separator 214 through the electromagnetic lens 207.

The E×B separator 214 includes a plurality of more than two magnetic poles of coils, and a plurality of more than two electrodes. For example, the E×B separator 214 includes four magnetic poles (electromagnetic deflection coils) whose phases are mutually shifted by 90°, and four electrodes (electrostatic deflection electrodes) whose phases are also mutually shifted by 90°. For example, by setting two opposing magnetic poles to be an N pole and an S pole, a directive magnetic field is generated by these plurality of magnetic poles. Also, for example, by applying electrical potentials V whose signs are opposite to each other to two opposing electrodes, a directive electric field is generated by these plurality of electrodes. Specifically, the E×B separator 214 generates an electric field and a magnetic field to be orthogonal to each other in a plane perpendicular to the traveling direction of the center beam (electron trajectory center axis) of the multiple primary electron beams 20. The electric field exerts a force in a fixed direction regardless of the traveling direction of electrons. In contrast, the magnetic field exerts a force according to Fleming's left-hand rule. Therefore, the direction of the force acting on electrons can be changed depending on the entering direction of electrons. With respect to the multiple primary electron beams 20 entering the E×B separator 214 from above, since the forces due to the electric field and the magnetic field cancel each other out, the beams 20 travel straight downward. In contrast, with respect to the multiple secondary electron beams 300 entering the E×B separator 214 from below, since both the forces due to the electric field and the magnetic field are exerted in the same direction, the multiple secondary electron beams 300 are bent obliquely upward, and separated from the multiple primary electron beams 20.

The multiple secondary electron beams 300 having been bent obliquely upward and separated from the multiple primary electron beams 20 are further bent by the deflector 218, and projected onto the multi-detector 222 while being refracted by the electromagnetic lenses 224 and 226. The multi-detector 222 detects the projected multiple secondary electron beams 300. Reflected electrons and secondary electrons may be projected on the multi-detector 222, or it is also acceptable that reflected electrons are diffused along the way and remaining secondary electrons are projected. The multi-detector 222 includes a two-dimensional sensor. Then, each secondary electron of the multiple secondary electron beams 300 collides with its corresponding region of the two-dimensional sensor, thereby generating electrons, and secondary electron image data is generated for each pixel. In other words, in the multi-detector 222, a detection sensor is disposed for each primary electron beam of the multiple primary electron beams 20. Then, the detection sensor detects a corresponding secondary electron beam emitted by irradiation with each primary electron beam. Therefore, each of a plurality of detection sensors in the multi-detector 222 detects an intensity signal of a secondary electron beam for an image resulting from irradiation with an associated primary electron beam. The intensity signal detected by the multi-detector 222 is output to the detection circuit 106.

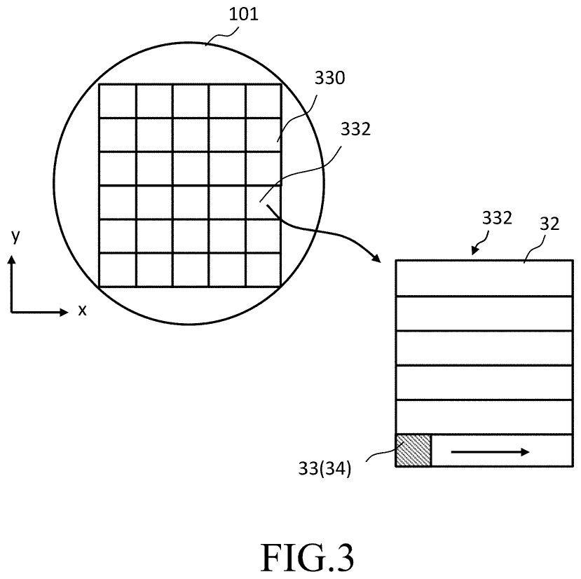

FIG. 3 is an illustration of an example of a plurality of chip regions formed on a semiconductor substrate, according to the embodiment 1. In FIG. 3, in the case of the substrate 101 being a semiconductor substrate (wafer), a plurality of chips (wafer dies) 332 are formed in an inspection region 330 of the semiconductor substrate (wafer). A mask pattern for one chip formed on an exposure mask substrate is reduced to, for example, ¼, and exposed/transferred onto each chip 332 by an exposure device (stepper, scanner, etc.) (not shown). The region of each chip 332 is divided, for example, in the y direction into a plurality of stripe regions 32 by a predetermined width. The scanning operation by the image acquisition mechanism 150 is carried out, for example, for each stripe region 32. The operation of scanning the stripe region 32 advances relatively in the x direction while the stage 105 is moved in the −x direction, for example. Each stripe region 32 is divided in the longitudinal direction into a plurality of rectangular regions 33. Beam application to a target rectangular region 33 is achieved by collectively deflecting all the multiple primary electron beams 20 by the main deflector 208.

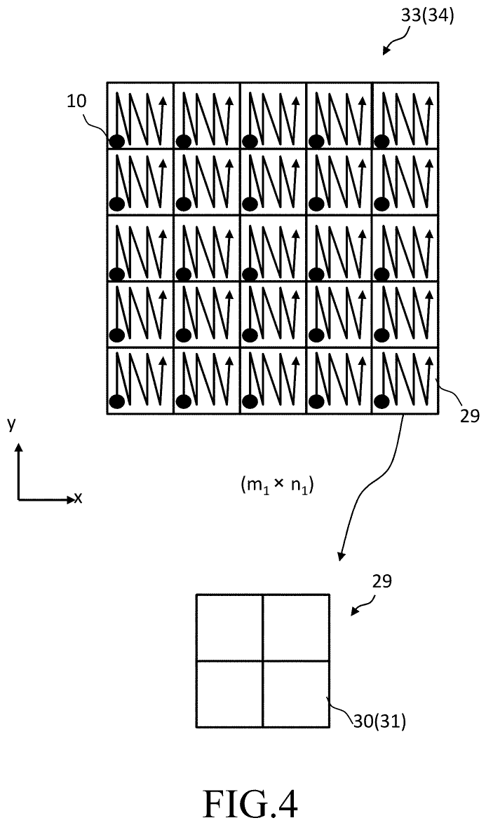

FIG. 4 is an illustration of a scanning operation with multiple beams according to the embodiment 1. FIG. 4 shows the case of multiple primary electron beams 20 of 5 rows×5 columns. The size of an irradiation region 34 which can be irradiated by one irradiation with the multiple primary electron beams 20 is defined by (the x-direction size obtained by multiplying the x-direction beam pitch of the multiple primary electron beams 20 on the substrate 101 by the number of x-direction beams)×(the y-direction size obtained by multiplying the y-direction beam pitch of the multiple primary electron beams 20 on the substrate 101 by the number of y-direction beams). Preferably, the width of each stripe region 32 is set to be the same as the y-direction size of the irradiation region 34, or to be the size reduced by the width of the scanning margin. In the case of FIGS. 3 and 4, the irradiation region 34 and the rectangular region 33 are of the same size. However, it is not limited thereto. The irradiation region 34 may be smaller than the rectangular region 33, or larger than it. A sub-irradiation region 29, which is surrounded by the x-direction beam pitch and the y-direction beam pitch and in which the beam concerned itself is located, is irradiated and scanned (scanning operation) with each beam of the multiple primary electron beams 20. Each primary electron beam 10 of the multiple primary electron beams 20 is associated with any one of the sub-irradiation regions 29 which are different from each other. At the time of each shot, each primary electron beam 10 is applied to the same position in the associated sub-irradiation region 29. The primary electron beam 10 is moved in the sub-irradiation region 29 by collective deflection of all the multiple primary electron beams 20 by the sub deflector 209. By repeating this operation, the inside of one sub-irradiation region 29 is irradiated with one primary electron beam 10 in order. Then, when scanning of one sub-irradiation region 29 is completed, the irradiation position is moved to an adjacent rectangular region 33 in the same stripe region 32 by collectively deflecting all of the multiple primary electron beams 20 by the main deflector 208. By repeating this operation, the inside of the stripe region 32 is irradiated in order. After completing scanning of one stripe region 32, the irradiation position is moved to the next stripe region 32 by moving the stage 105 and/or by collectively deflecting all of the multiple primary electron beams 20 by the main deflector 208. As described above, a secondary electron image of each sub-irradiation region 29 is acquired by irradiation with each primary electron beam 10. By combining secondary electron images of respective sub-irradiation regions 29, a secondary electron image of the rectangular region 33, a secondary electron image of the stripe region 32, or a secondary electron image of the chip 332 is configured.

As shown in FIG. 4, each sub-irradiation region 29 is divided into a plurality of rectangular frame regions 30, and a secondary electron image (image to be inspected) in units of frame regions 30 is used for inspection. In the example of FIG. 4, one sub-irradiation region 29 is divided into four frame regions 30, for example. However, the number used for the dividing is not limited to four, and other number may be used for the dividing.

It is also preferable to group, for example, a plurality of chips 332 aligned in the x direction in the same group, and to divide each group into a plurality of stripe regions 32 by a predetermined width in the y direction, for example. Then, moving between stripe regions 32 is not limited to the moving in each chip 332, and it is also preferable to move in each group.

When the multiple primary electron beams 20 irradiate the substrate 101 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, when the inside of the sub-irradiation region 29 is scanned, the emission position of each secondary electron beam changes every second in the sub-irradiation region 29. Thus, the deflector 218 collectively deflects the multiple secondary electron beams 300 so that each secondary electron beam whose emission position has changed as described above may be applied to a corresponding detection region of the multi-detector 222.

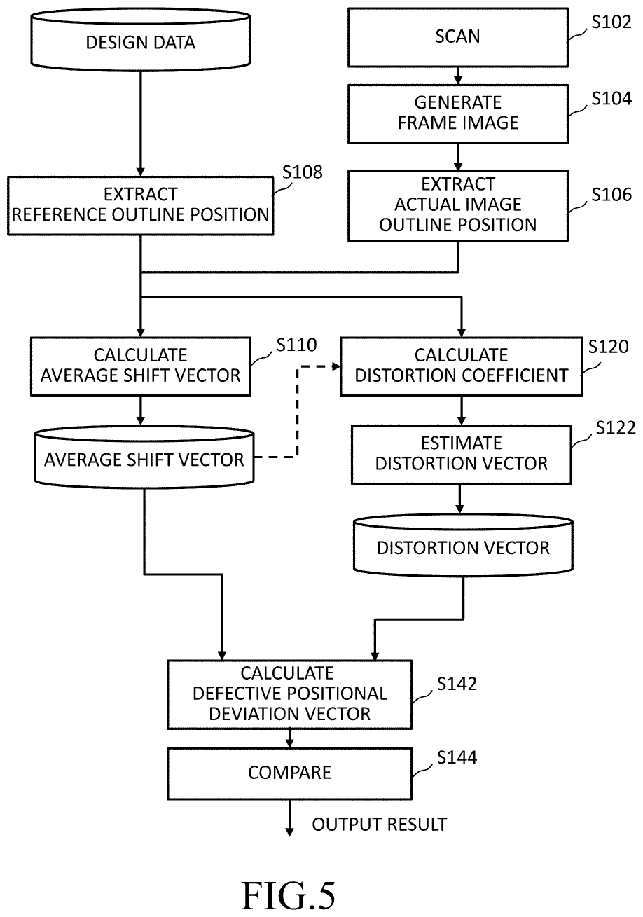

FIG. 5 is a flowchart showing main steps of an inspection method according to the embodiment 1. In FIG. 5, the inspection method of the embodiment 1 executes a series of steps: a scanning step (S102), a frame image generation step (S104), an actual image outline position extraction step (S106), a reference outline position extraction step (S108), an average shift vector calculation step (S110), an alignment step (S112), a distortion coefficient calculation step (S120), a distortion vector estimation step (S122), a defective positional deviation vector calculation step (S142), and a comparison step (S144). The average shift vector calculation step (S110) may be omitted from the configuration. Alternatively, the distortion coefficient calculation step (S120) and the distortion vector estimation step (S122) may be omitted from the configuration instead of omitting the average shift vector calculation step (S110).

In the scanning step (S102), the image acquisition mechanism 150 acquires an image of the substrate 101 on which a figure pattern is formed. Specifically, the image acquisition mechanism 150 irradiates the substrate 101, on which a plurality of figure patterns are formed, with the multiple primary electron beams 20 to acquire a secondary electron image of the substrate 101 by detecting the multiple secondary electron beams 300 emitted from the substrate 101 due to the irradiation with the multiple primary electron beams 20. As described above, reflected electrons and secondary electrons may be projected on the multi-detector 222, or alternatively, reflected electrons are diffused along the way, and only remaining secondary electrons (the multiple secondary electron beams 300) may be projected thereon.

As described above, the multiple secondary electron beams 300 emitted from the substrate 101 due to the irradiation with the multiple primary electron beams 20 are detected by the multi-detector 222. Detected data (measured image data: secondary electron image data: inspection image data) on the secondary electron of each pixel in each sub irradiation region 29 detected by the multi-detector 222 is output to the detection circuit 106 in order of measurement. In the detection circuit 106, the detected data in analog form is converted into digital data by an A-D converter (not shown), and stored in the chip pattern memory 123. Then, acquired measured image data is transmitted to the comparison circuit 108, together with information on each position from the position circuit 107.

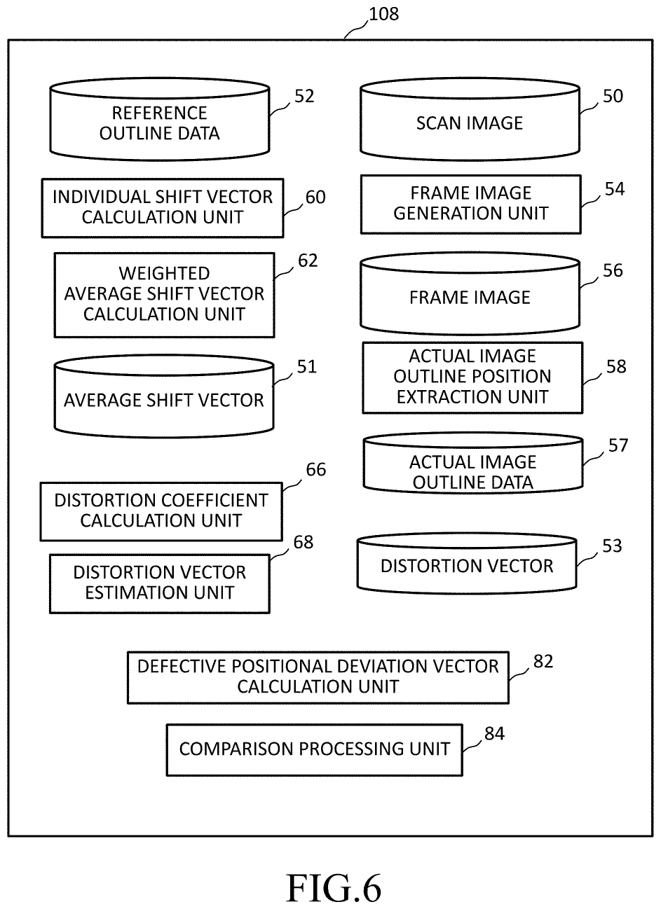

FIG. 6 is a block diagram showing an example of a configuration in a comparison circuit according to the embodiment 1. In FIG. 6, in the comparison circuit 108 of the embodiment 1, there are arranged storage devices 50, 51, 52, 53, 56, and 57 such as magnetic disk drives, a frame image generation unit 54, an actual image outline position extraction unit 58, an individual shift vector calculation unit 60, a weighted average shift vector calculation unit 62, a distortion coefficient calculation unit 66, a distortion vector estimation unit 68, a defective positional deviation vector calculation unit 82, and a comparison processing unit 84. Each of the “units” such as the frame image generation unit 54, the actual image outline position extraction unit 58, the individual shift vector calculation unit 60, the weighted average shift vector calculation unit 62, the distortion coefficient calculation unit 66, the distortion vector estimation unit 68, the defective positional deviation vector calculation unit 82, and the comparison processing unit 84 includes processing circuitry. The processing circuitry includes an electric circuit, computer, processor, circuit board, quantum circuit, semiconductor device, or the like. Further, common processing circuitry (the same processing circuitry), or different processing circuitry (separate processing circuitry) may be used for each of the “units”. Input data required in the frame image generation unit 54, the actual image outline position extraction unit 58, the individual shift vector calculation unit 60, the weighted average shift vector calculation unit 62, the distortion coefficient calculation unit 66, the distortion vector estimation unit 68, the defective positional deviation vector calculation unit 82, and the comparison processing unit 84, or calculated results are stored in a memory (not shown) or in the memory 118 each time.

The measured image data (scan image) transmitted into the comparison circuit 108 is stored in the storage device 50.

In the frame image generation step (S104), the frame image generation unit 54 generates a frame image 31 of each of a plurality of frame regions 30 obtained by further dividing the image data of the sub-irradiation region 29 acquired by a scanning operation with each primary electron beam 10. In order to prevent missing an image, it is preferable that margin regions overlap each other in respective frame regions 30. The generated frame image 31 is stored in the storage device 56.

In the actual image outline position extraction step (S106), the actual image outline position extraction unit 58 extracts, for each frame image 31, a plurality of outline positions (actual image outline positions) of each figure pattern in the frame image 31 concerned.

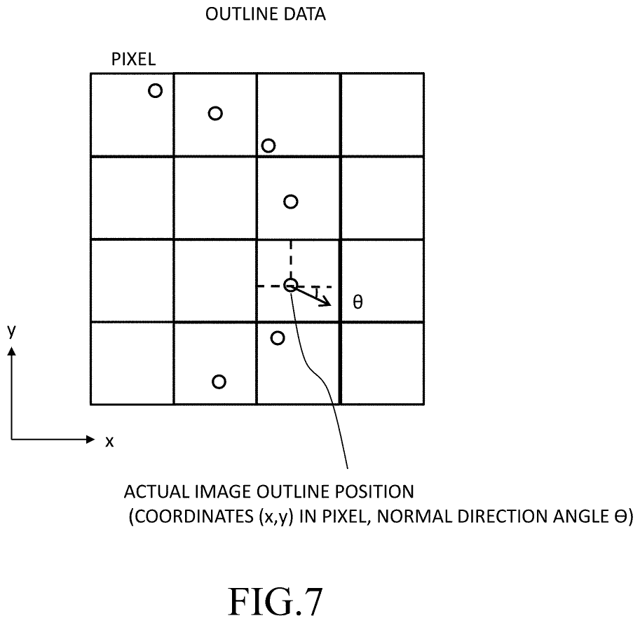

FIG. 7 is a diagram showing an example of an actual image outline position according to the embodiment 1. The method for extracting an outline position may be the conventional one. For example, differential filter processing for differentiating each pixel in the x and y directions by using a differentiation filter, such as a Sobel filter is performed to combine x-direction and y-direction primary differential values. Then, the peak position of a profile using the combined primary differential values is extracted as an outline position on an outline (actual image outline). FIG. 7 shows the case where one outline position is extracted for each of a plurality of outline pixels through which an actual image outline passes. The outline position is extracted per sub-pixel in each outline pixel. In the example of FIG. 7, the outline position is represented by coordinates (x, y) in a pixel. Further, shown is a normal direction angle θ at each outline position of the outline approximated by fitting a plurality of outline positions by a predetermined function. The normal direction angle θ is defined by a clockwise angle to the x axis. Information on each obtained actual image outline position (actual image outline data) is stored in the storage device 57.

In the reference outline position extraction step (S108), the reference outline position extraction circuit 112 extracts a plurality of reference outline positions for comparing with a plurality of actual image outline positions. A reference outline position may be extracted from design data. Alternatively, first, a reference image is generated from design data, and a reference outline position may be extracted using the reference image by the same method as that of the case of the frame image 31 being a measured image. Alternatively, a plurality of reference outline positions may be extracted by the other conventional method.

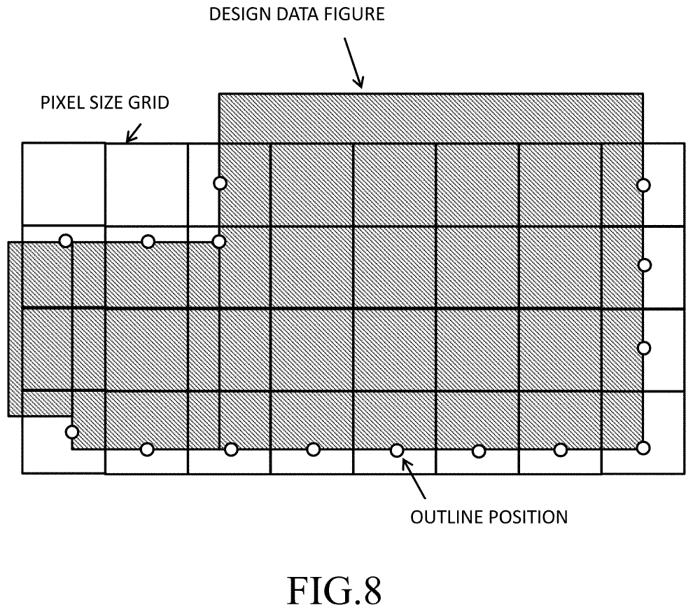

FIG. 8 is a diagram for explaining an example of a method for extracting a reference outline position according to the embodiment 1. The case of FIG. 8 shows an example of a method for extracting a reference outline position from design data. In FIG. 8, the reference outline position extraction circuit 112 reads design pattern data (design data) being a basis of a pattern formed on the substrate 101 from the storage device 109. The reference outline position extraction circuit 112 sets grids, each being the size of a pixel, for the design data. The midpoint of a straight line in a quadrangle corresponding to a pixel is defined as a reference outline position. If there is a corner of a figure pattern, the corner vertex is defined as a reference outline position. If there are a plurality of corners, the intermediate point of the corner vertices is defined as a reference outline position. By the process described above, the outline position of a figure pattern as a design pattern in the frame region 30 can be extracted with sufficient accuracy. Information (reference outline data) on each obtained reference outline position is output to the comparison circuit 108. Then, in the comparison circuit 108, reference outline data is stored in the storage device 52.

If omitting the average shift vector calculation step (S110), it proceeds to the distortion coefficient calculation step (S120). If not omitting the average shift vector calculation step (S110), it proceeds to the average shift vector calculation step (S110).

In the average shift vector calculation step (S110), using a plurality of actual image outline positions on an actual image outline of a figure pattern in the frame image 31 and a plurality of reference outline positions, the weighted average shift vector calculation unit 62 calculates an average shift vector Dₐᵥₑ weighted in the normal direction with respect to the actual image outline for performing, by a parallel shift, an alignment between a plurality of actual image outline positions and a plurality of reference outline positions. Specifically, it operates as follows:

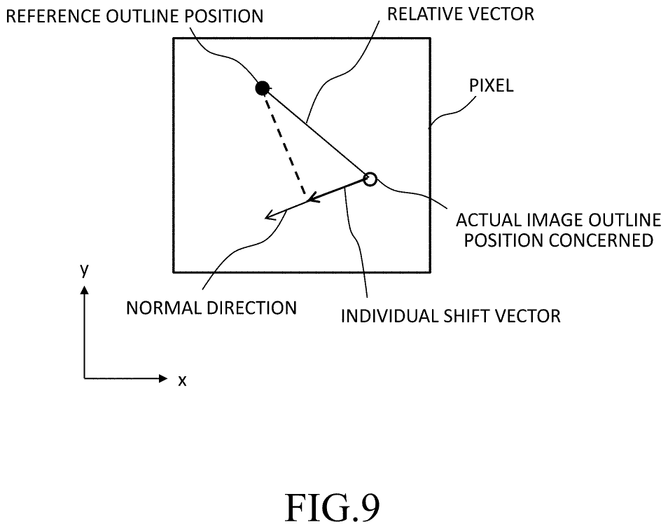

FIG. 9 is a diagram showing an example of an individual shift vector according to the embodiment 1. As shown in FIG. 9, the individual shift vector of the embodiment 1 is a component obtained by projecting a relative vector between the actual image outline position concerned and the reference outline position corresponding to the actual image outline position concerned, in the normal direction at the actual image outline position concerned. The individual shift vector calculation unit 60 calculates an individual shift vector for each actual image outline position of a plurality of actual image outline positions. As the reference outline position corresponding to the actual image outline position concerned, the reference outline position closest from the actual image outline position concerned is used.

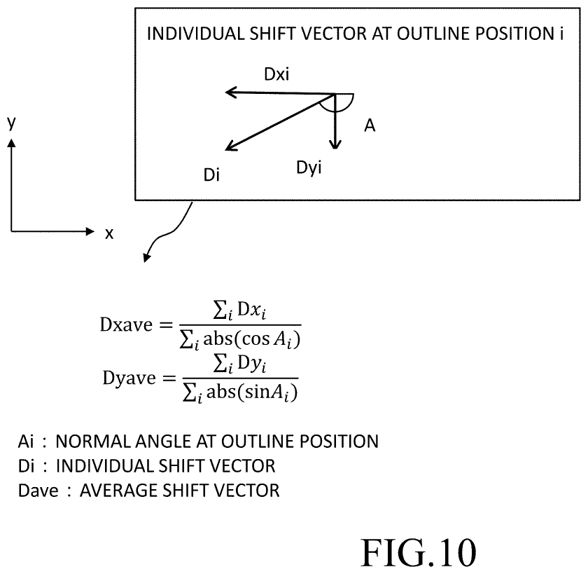

FIG. 10 is a diagram for explaining a method of calculating a weighted average shift vector according to the embodiment 1. In FIG. 10, the weighted average shift vector calculation unit 62 calculates, for each frame image 31, an average shift vector Dₐᵥₑ weighted in the normal direction, using an x-direction component Dₓᵢ and a y-direction component D_{yi} of an individual shift vector Dᵢ of an actual image outline position i, and a normal direction angle Aᵢ. The actual image outline position i indicates the i-th actual image outline position in the same frame image 31. Although there is no information on the shift vector component in the tangential direction of the actual image outline orthogonal to the normal direction, the shift amount (vector amount) is zero. In order to distinguish from the case of the true shift amount being zero (not to generate an error in calculation of an average), calculating is performed while weighting in a normal direction. In FIG. 10, there is shown an equation for calculating an x-direction component Dₓₐᵥₑ and a y-direction component D_{yave} of the average shift vector Dₐᵥₑ. The x-direction component Dₓₐᵥₑ of the average shift vector Dₐᵥₑ can be obtained by dividing the total of x-direction components Dₓᵢ of individual shift vectors Dᵢ by the total of absolute values of cosAᵢ. The y-direction component D_{yave} of the average shift vector Dₐᵥₑ can be obtained by dividing the total of y-direction components D_{yi} of individual shift vectors Dᵢ by the total of absolute values of sinAᵢ. Information on the average shift vector Dₐᵥₑ is stored in the storage device 51.

If omitting the distortion coefficient calculation step (S120) and the distortion vector estimation step (S122), it proceeds to the positional deviation vector calculation step (S142).

In the defective positional deviation vector calculation step (S142), the defective positional deviation vector calculation unit 82 calculates a defective positional deviation vector according to the average shift vector Dₐᵥₑ between each of a plurality of actual image outline positions and its corresponding reference outline position.

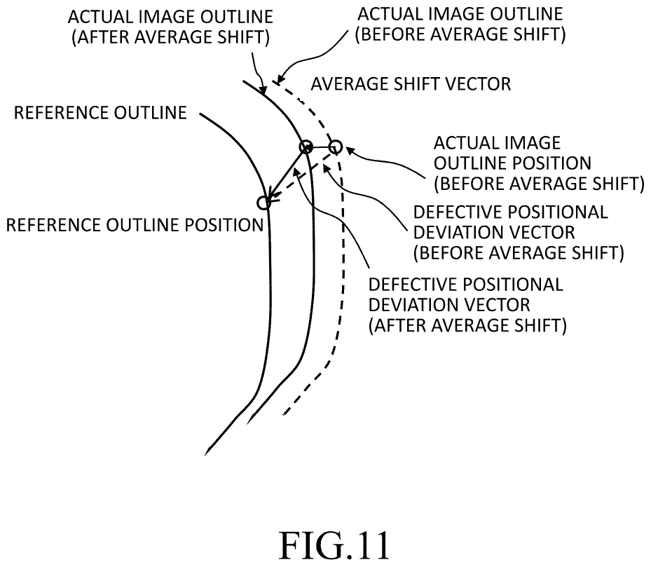

FIG. 11 is an illustration for explaining a defective positional deviation vector according to an average shift vector according to the embodiment 1. As described above, deviation between outlines includes a positional deviation due to distortion of an image itself in addition to a positional deviation due to defects. Therefore, in order to accurately inspect whether a defect exists in outlines, it is necessary to perform an alignment with high precision between an actual image outline of the frame image 31 and a reference outline, for correcting a deviation due to its own distortion of the frame image 31 being a measured image. In a positional deviation vector (relative vector) between an actual image outline position before alignment and a reference outline position, a distortion of an image is included. In the example of FIG. 11, a common average shift vector Dₐᵥₑ in the same frame image 31 is used as a positional deviation component of distortion. Then, instead of separately performing alignment processing for correcting an image distortion, the defective positional deviation vector calculation unit 82 calculates a defective positional deviation vector (after average shift) by subtracting an average shift vector Dₐᵥₑ from the positional deviation vector (relative vector) between an actual image outline position before alignment and a reference outline position. Thereby, the same effect as alignment can be acquired.

In the comparison step (S144), the comparison processing unit 84 (comparison unit) compares, using the average shift vector Dₐᵥₑ, an actual image outline with a reference outline. Specifically, the comparison processing unit 84 determines it as a defect when the magnitude (distance) of a defective positional deviation vector according to the average shift vector Dₐᵥₑ between each of a plurality of actual image outline positions and its corresponding reference outline position exceeds a determination threshold. The comparison result is output to the storage device 109, the monitor 117, or the memory 118.

As described above, by performing distortion correction by parallel shifting using the average shift vector Dₐᵥₑ, it is possible to inspect a positional deviation component due to a defect, which is obtained by excluding a positional deviation amount due to distortion from the positional deviation amount. Further, by performing weighting in a normal direction, contribution of a tangential direction component having low reliability can be reduced.

With respect to distortion of an image, there may remain a correction residual error which cannot be completely corrected by parallel shifting. Then, next, a configuration which can perform distortion correction more highly accurately than the parallel shifting will be explained.

Specifically, the case where the average shift vector calculation step (S110) is omitted will be described. In that case, after extracting an actual image outline position and a reference outline position, it proceeds to the distortion coefficient calculation step (S120). Alternatively, the case where the average shift vector calculation step (S110), the distortion coefficient calculation step (S120), and the distortion vector estimation step (S122) are not omitted will be described. In that case, after the average shift vector calculation step (S110), it proceeds to the distortion coefficient calculation step (S120).

In the distortion coefficient calculation step (S120), the distortion coefficient calculation unit 66 calculates, using a plurality of actual image outline positions on the actual image outline of a figure pattern in the frame image 31 and a plurality of reference outline positions on the reference outline for comparing with the actual image outline, distortion coefficients by performing weighting in the normal direction at each of the plurality of actual image outline positions caused by distortion of the frame image 31. The distortion coefficient calculation unit 66 calculates the distortion coefficients, using a two-dimensional distortion model.

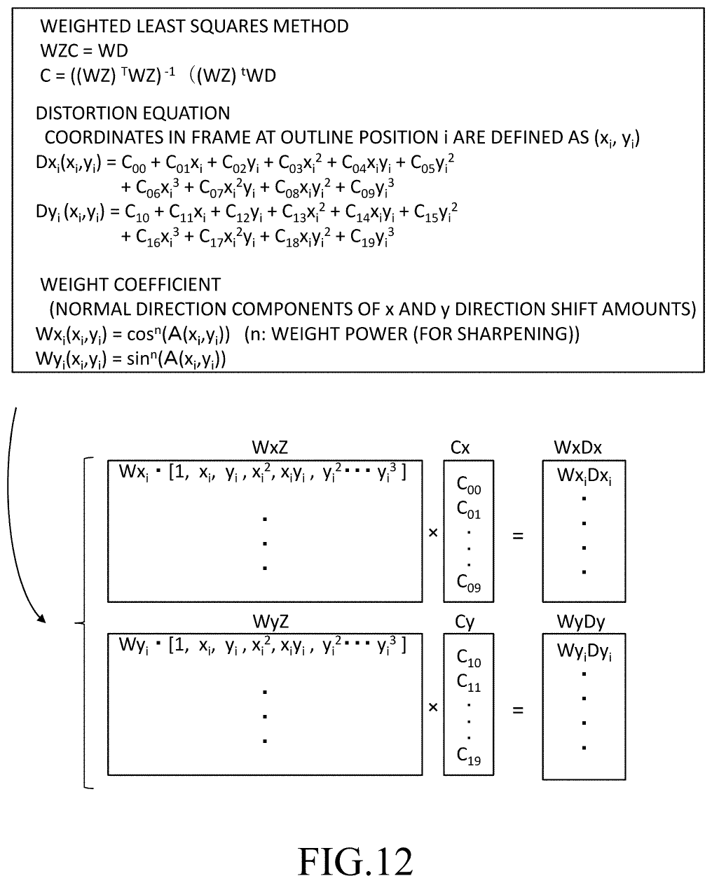

FIG. 12 is a diagram for explaining a two-dimensional distortion model according to the embodiment 1. The example of FIG. 12 shows a two-dimensional distortion model using a distortion equation which performs fitting an individual shift vector Dᵢ by a polynomial. Furthermore, weighting according to a weighting coefficient Wᵢ in the normal direction is performed. The two-dimensional distortion model of FIG. 12 uses a third-order polynomial. Therefore, in the two-dimensional distortion model of FIG. 12, using a weighting coefficient W, an equation matrix Z, distortion coefficients C of the third-order polynomial, and an individual shift vector D, an equation of the two-dimensional distortion model represented by the following equation (1) is used.

WZC=WD (1)

The distortion coefficient calculation unit 66 calculates distortion coefficients C so that an error of the equation (1) may become small with respect to the whole of actual image outline positions i in the frame image 31. Specifically, it is calculated as follows: The equation (1) is divided into an x-direction component and a y-direction component to be defined. The distortion equation of the x-direction component is defined by the following equation (2-1) using coordinates (xᵢ,yᵢ) in the frame region 30 at the actual image outline position i. The distortion equation of the y-direction component is defined by the following equation (2-2) using coordinates (xᵢ,yᵢ) in the frame region 30 of the actual image outline position i.

Dxᵢ(xᵢ,yᵢ)=C₀₀+C₀₁xᵢ+C₀₂xᵢ²+C₀₃xᵢ²+C₀₄xᵢyᵢ+C₀₅yᵢ²C₀₆xᵢ³+C₀₇xᵢ²yᵢ+C₀₈xᵢyᵢ²+C₀₉yᵢ³ (2-1)

Dyᵢ(xᵢ,yᵢ)=C₁₀+C₁₁xᵢ+C₁₂xᵢ²+C₁₃xᵢ²+C₁₄xᵢyᵢ+C₁₅yᵢ²C₁₆xᵢ³+C₁₇xᵢ²yᵢ+C₁₈xᵢyᵢ²+C₁₉yᵢ³ (2-2)

Here, distortion is represented by the third-order polynomial. Further, it can be represented by an equation of the second order or less, or an equation of the fourth order or more depending on actual distortion complexity.

Therefore, the distortion coefficients Cx of the x-direction component are coefficients C₀₀, C₀₁, C₀₂, . . . , C₀₉ of the third-order polynomial. The distortion coefficients Cy of the y-direction are coefficients C₁₀, C₁₁, C₁₂, . . . , C₁₉ of the same third-order polynomial. Further, the element of each row of the equation matrix Z is each term (1, xᵢ, yᵢ, xᵢ², xᵢyᵢ, yᵢ², xᵢ³, xᵢ²yᵢ, xᵢyᵢ^{2, y}ᵢ³) in the case where each coefficient of the third-order polynomial is 1.

The weighting coefficient Wxᵢ(xᵢ,yᵢ) of each actual image outline position i of the x-direction component is defined by the following equation (3-1) using a normal direction angle A(xᵢ,yᵢ) and a weight power n. Similarly, the weighting coefficient Wyᵢ(xᵢ,yᵢ) of each actual image outline position i of the y-direction component is defined by the following equation (3-2) using the normal direction angle A(xᵢ,yᵢ) and the weight power n.

Wxᵢ(xᵢ,yᵢ)=cosⁿ(Aᵢ(x,yᵢ)) (3-1)

Wyᵢ(xᵢ,yᵢ)=sinⁿ(Aᵢ(xᵢ,yᵢ)) (3-2)

Here, sharpening is performed by exponentiating the weight. Further, sharpening the weight can be performed by using a general function, such as a logistic function and an arc tangent function.

Dividing the equation (1) into an x-direction component and a y-direction component, each of them is defined by a matrix as shown in FIG. 12. By solving the equation of the matrix, the distortion coefficients Cx of the x-direction component and the distortion coefficients Cy of the y-direction are calculated. Since the number of actual image outline positions i is usually larger than the number (nine) of distortion coefficients C₀₀, C₀₁, C₀₂, . . . , C₀₉ of the x-direction component, the calculation may be performed such that an error becomes as small as possible. The calculation may also be similarly performed for the distortion coefficients C₁₀, C₁₁, C₁₂, . . . , C₁₉ of the y-direction component. It is here preferable to obtain the coefficients C by performing calculation as shown in the equation (4), applying the least-squares method to the equation (1).

C=((WZ)^{T}(WZ))⁻¹(WZ)^{T}WD (4)

(M⁻¹ represents an inverse matrix of the matrix M, and M^{T} represents a transposed matrix of the matrix M)

In calculating the distortion coefficients, if omitting the average shift vector calculation step (S110), the x-direction component Dxᵢ and the y-direction component Dyᵢ of the individual shift vector Dᵢ and the normal direction angle Aᵢ at the actual image outline position i explained in FIG. 10 can be used as Dxᵢ(xᵢ,yᵢ), Dyᵢ(xᵢ,yᵢ), and Aᵢ(xᵢ,yᵢ) shown in FIG. 12. When, without omitting the average shift vector calculation step (S110), calculating distortion coefficients after the average shift vector calculation step (S110), as Dxᵢ(xᵢ,yᵢ), Dyᵢ(xᵢ,yᵢ), and Aᵢ(xᵢ,yᵢ) shown in FIG. 12, the distortion coefficients can be calculated by correcting each individual shift vector Dᵢ by the average shift vector Dₐᵥₑ. Here, the correcting can also be performed by obtaining a shift vector by a method other than the average shift vector calculation step. For example, the shift vector may be obtained by applying a general alignment method to two inspection images in a die-to-die inspection.

In the distortion vector estimation step (S122), the distortion vector estimation unit 68 estimates, for each of a plurality of actual image outline positions, a distortion vector at coordinates (xᵢ,yᵢ) in the frame by using the distortion coefficients C. Specifically, a distortion vector Dhᵢ is estimated by combining the distortion amount Dxᵢ of the x direction and the distortion amount Dyᵢ of the y direction, which are obtained by performing, with respect to coordinates (xᵢ,yᵢ) in the frame, calculation of the equation (2-1) using an obtained distortion coefficients C₀₀, C₀₁, C₀₂, . . . , C₀₉ of the x-direction component and calculation of the equation (2-2) using an obtained distortion coefficients C₁₀, C₁₁, C₁₂, . . . , C₁₉ of the y-direction component.

In the defective positional deviation vector calculation step (S142), the defective positional deviation vector calculation unit 82 calculates a defective positional deviation vector according to a distortion vector Dhᵢ between each of a plurality of actual image outline positions and its corresponding reference outline position.

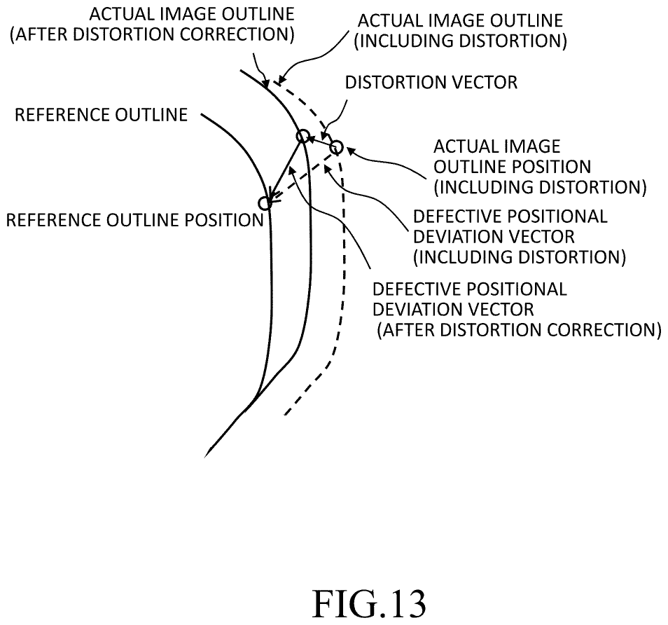

FIG. 13 is an illustration for explaining a defective positional deviation vector according to a distortion vector according to the embodiment 1. As described above, deviation between outlines includes a positional deviation due to distortion of an image itself in addition to a positional deviation due to defects. Therefore, in order to accurately inspect whether a defect exists in outlines, it is necessary to perform an alignment with high precision between an actual image outline of the frame image 31 and a reference outline, for correcting a deviation due to its own distortion of the frame image 31 being a measured image. In a positional deviation vector (relative vector) between an actual image outline position before alignment and a reference outline position, a distortion of an image is included. In the example of FIG. 13, an individual distortion vector Dhᵢ is used as a positional deviation component of distortion. Then, instead of separately performing alignment processing for correcting an image distortion, the defective positional deviation vector calculation unit 82 calculates a defective positional deviation vector (after distortion correction) by subtracting an individual distortion vector Dhᵢ from the positional deviation vector (relative vector) between an actual image outline position before alignment and a reference outline position. Thereby, the same effect as alignment can be acquired.

When, without omitting the average shift vector calculation step (S110), calculating distortion coefficients after the average shift vector calculation step (S110), the defective positional deviation vector calculation unit 82 obtains a defective positional deviation vector (after distortion correction) by further subtracting the average shift vector Dₐᵥₑ in addition to the individual distortion vector Dhᵢ from the positional deviation vector (relative vector) between an actual image outline position before alignment and a reference outline position.

In the comparison step (S144), the comparison processing unit 84 (comparison unit) compares, using the individual distortion vector Dᵢ at each actual image outline position, an actual image outline with a reference outline. Specifically, the comparison processing unit 84 determines it to be a defect when the magnitude (distance) of a defective positional deviation vector according to the individual distortion vector Dhᵢ between each of a plurality of actual image outline positions and its corresponding reference outline position exceeds a determination threshold. In other words, with respect to each actual image outline position, the comparison processing unit 84 determines it to be a defect when the magnitude of a defective positional deviation vector from the position after correction by the individual distortion vector Dᵢ to a corresponding reference outline position exceeds a determination threshold. The comparison result is output to the storage device 109, the monitor 117, or the memory 118.

According to what is described above, it is possible to correct a rotational error, a magnification error, an orthogonal error, or a higher order distortion which are not completely corrected by a parallel shift. Thereby, it is possible to inspect a positional deviation component due to defects, which is obtained by further accurately removing a positional deviation due to distortion from the positional deviation amount. Furthermore, by performing weighting in a normal direction, contribution of a tangential direction component having low reliability can be reduced.

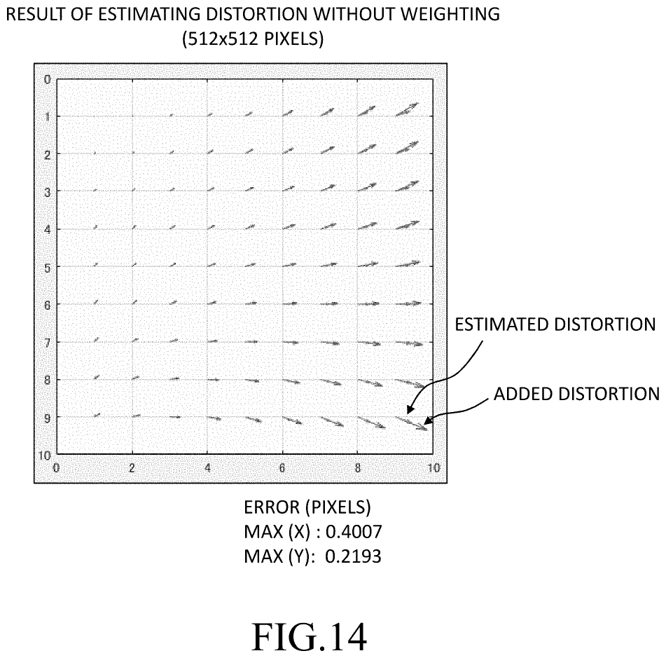

FIG. 14 is a diagram showing an example of a measurement result of a positional deviation amount of an image to which a distortion is added, and a positional deviation amount for which distortion is estimated without performing weighting in a normal direction according to the embodiment 1. FIG. 14 shows a measurement result of a positional deviation amount (distortion added) in the case where distortion is added to the frame image 31 of 512×512 pixels, (where the measurement points are 9×9 points in the frame). Further, FIG. 14 shows a result (distortion estimated) of estimating a distortion vector by obtaining distortion coefficients without performing weighting the positional deviation amount at each such position in a normal direction. As shown in FIG. 14, when not performing weighting in a normal direction, it turns out that an error remains between an added distortion and an estimated distortion.

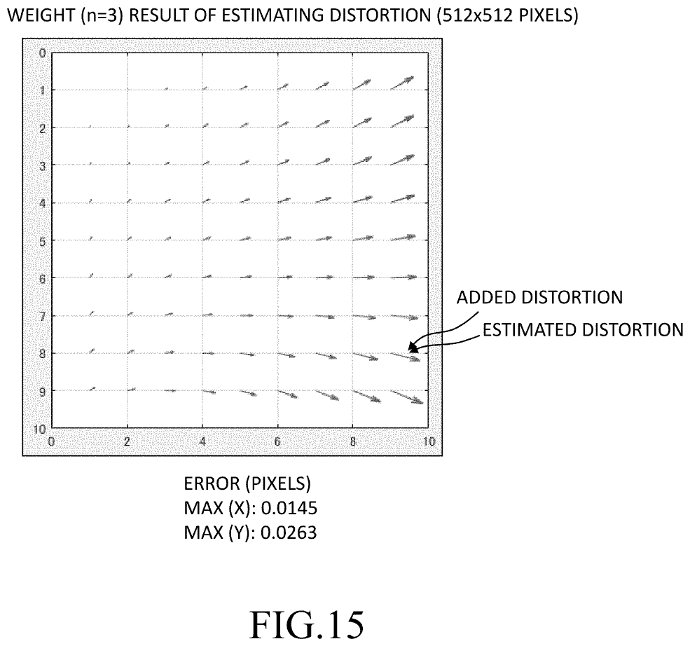

FIG. 15 is a diagram showing an example of a measurement result of a positional deviation amount of an image to which a distortion is added, and a positional deviation amount for which distortion is estimated with performing weighting in a normal direction according to the embodiment 1. FIG. 15 shows a measurement result of a positional deviation amount (distortion added) in the case where distortion is added to the frame image 31 of 512×512 pixels, (where the measurement points are 9×9 points in the frame). Further, FIG. 15 shows a result (estimated distortion) of estimating a distortion vector by obtaining distortion coefficients in the case of weight power n of the weight coefficients of the equations (3-1) and (3-2) being n=3 for a weight in a normal direction in the positional deviation amount at each such position. As shown in FIG. 15, when performing weighting in a normal direction, the error between an added distortion and an estimated distortion can be reduced.

In the examples described above, the case (die-to-database inspection) has been described where a reference image generated based on design data or a reference outline position (or reference outline) obtained from design data is compared with a frame image being a measured image. However, it is not limited thereto. For example, the case (die-to-die inspection) where, in a plurality of dies on each of which the same pattern is formed, a frame image of one die is compared with a frame image of another die is also preferable. In the case of the die-to-die inspection, as reference outline positions, a plurality of outline positions in the frame image 31 of the die 2 may be extracted by the same method as that of extracting a plurality of outline positions in the frame image 31 of the die 1. Then, the distance between them may be calculated.

As described above, according to the embodiment 1, an inspection according to a positional deviation due to distortion of a measured image can be performed. Further, by performing weighting in a normal direction, contribution of a tangential direction component having low reliability can be reduced. Furthermore, the accuracy of calculating distortion coefficients can be increased without performing processing of a large calculation amount. Therefore, the defect detection sensitivity in an appropriate inspection time can be improved.

In the above description, a series of “ . . . circuits” includes processing circuitry. The processing circuitry includes an electric circuit, computer, processor, circuit board, quantum circuit, semiconductor device, or the like. Each “ . . . circuit” may use common processing circuitry (the same processing circuitry), or different processing circuitry (separate processing circuitry). A program for causing a processor, etc. to execute processing may be stored in a recording medium, such as a magnetic disk drive, flush memory, etc. For example, the position circuit 107, the comparison circuit 108, the reference outline position extraction circuit 112, the stage control circuit 114, the lens control circuit 124, the blanking control circuit 126, and the deflection control circuit 128 may be configured by at least one processing circuit described above.

Embodiments have been explained referring to specific examples described above. However, the present invention is not limited to these specific examples. Although FIG. 1 shows the case where the multiple primary electron beams 20 are formed by the shaping aperture array substrate 203 irradiated with one beam from the electron gun 201 serving as an irradiation source, it is not limited thereto. The multiple primary electron beams 20 may be formed by irradiation with a primary electron beam from each of a plurality of irradiation sources.

While the apparatus configuration, control method, and the like not directly necessary for explaining the present invention are not described, some or all of them can be appropriately selected and used on a case-by-case basis when needed.

In addition, any alignment method, distortion correction method, pattern inspection method, and pattern inspection apparatus that include elements of the present invention and that can be appropriately modified by those skilled in the art are included within the scope of the present invention.

### Industrial Applicability

The present invention relates to a pattern inspection apparatus and a pattern inspection method. For example, it can be applied to an inspection apparatus that performs inspection using a secondary electron image of a pattern emitted from the substrate irradiated with multiple electron beams, an inspection apparatus that performs inspection using an optical image of a pattern acquired from the substrate irradiated with ultraviolet rays, and a method thereof.

### REFERENCE SIGNS LIST

10 Primary Electron Beam

20 Multiple Primary Electron Beams

22 Hole

29 Sub Irradiation Region

30 Frame Region

31 Frame Image

32 Stripe Region

33 Rectangular Region

34 Irradiation Region

50, 51, 52, 53, 56, 57 Storage Device

54 Frame Image Generation Unit

58 Actual Image Outline Position Extraction Unit

60 Individual Shift Vector Calculation Unit

62 Weighted Average Shift Vector Calculation Unit

66 Distortion Coefficient Calculation Unit

68 Distortion Vector Estimation Unit

82 Defective Positional Deviation Vector Calculation Unit

84 Comparison Processing Unit

100 Inspection Apparatus

101 Substrate

102 Electron Beam Column

103 Inspection Chamber

105 Stage

106 Detection Circuit

107 Position Circuit

108 Comparison Circuit

109 Storage Device

110 Control Computer

112 Reference Outline Position Extraction Circuit

114 Stage Control Circuit

117 Monitor

118 Memory

120 Bus

122 Laser Length Measuring System

123 Chip Pattern Memory

124 Lens Control Circuit

126 Blanking Control Circuit

128 Deflection Control Circuit

142 Drive Mechanism

144, 146, 148 DAC Amplifier

150 Image Acquisition Mechanism

160 Control System Circuit

201 Electron Gun

202 Electromagnetic Lens

203 Shaping Aperture Array Substrate

205, 206, 207, 224, 226 Electromagnetic Lens

208 Main Deflector

209 Sub Deflector

212 Collective Blanking Deflector

213 Limiting Aperture Substrate

214 Beam Separator

216 Mirror

218 Deflector

222 Multi-Detector

300 Multiple Secondary Electron Beams

330 Inspection Region

332 Chip

1. A pattern inspection apparatus comprising:
an image acquisition mechanism configured to acquire an inspection image of a substrate on which a figure pattern is formed;
a distortion coefficient calculation circuit configured to calculate, using a plurality of actual image outline positions on an actual image outline of the figure pattern in the inspection image and a plurality of reference outline positions on a reference outline to be compared with the actual image outline, distortion coefficients by performing weighting in a predetermined direction at each actual image outline position of the plurality of actual image outline positions caused by distortion of the inspection image;
a distortion vector estimation circuit configured to estimate, for the each actual image outline position of the plurality of actual image outline positions, a distortion vector by using the distortion coefficients; and
a comparison circuit configured to compare, using the distortion vector at the each actual image outline position, the actual image outline with the reference outline.

2. The pattern inspection apparatus according to claim 1, wherein the distortion coefficient calculation circuit calculates the distortion coefficients by using a two-dimensional distortion model.

3. The pattern inspection apparatus according to claim 1, wherein, with respect to the each actual image outline position, the comparison circuit determines it to be a defect in a case where a magnitude of a positional deviation vector from a position after correction by the distortion vector to a corresponding reference outline position exceeds a determination threshold.

4. A pattern inspection apparatus comprising:
an image acquisition mechanism configured to acquire an inspection image of a substrate on which a figure pattern is formed;
an average shift vector calculation circuit configured to calculate, using a plurality of actual image outline positions on an actual image outline of the figure pattern in the inspection image and a plurality of reference outline positions to be compared with the plurality of actual image outline positions, an average shift vector weighted in a predetermined direction with respect to the actual image outline for performing, by a parallel shift, an alignment between the plurality of actual image outline positions and the plurality of reference outline positions; and
a comparison circuit configured to compare, using the average shift vector, the actual image outline with a reference outline.

5. The pattern inspection apparatus according to claim 4, wherein the comparison circuit determines it to be a defect in a case where a magnitude of a defective positional deviation vector according to the average shift vector between each of the plurality of actual image outline positions and its corresponding reference outline position exceeds a determination threshold.

6. A pattern inspection method comprising:
acquiring an inspection image of a substrate on which a figure pattern is formed;
calculating, using a plurality of actual image outline positions on an actual image outline of the figure pattern in the inspection image and a plurality of reference outline positions on a reference outline to be compared with the actual image outline, distortion coefficients by performing weighting in a predetermined direction at each actual image outline position of the plurality of actual image outline positions caused by distortion of the inspection image;
estimating, for the each actual image outline position of the plurality of actual image outline positions, a distortion vector by using the distortion coefficients; and
comparing, using the distortion vector at the each actual image outline position, the actual image outline with the reference outline, and outputting a result.

7. The pattern inspection method according to claim 6, wherein the distortion coefficients are calculated using a two-dimensional distortion model.

8. The pattern inspection method according to claim 6, wherein, with respect to the each actual image outline position, it is determined to be a defect in a case where a magnitude of a positional deviation vector from a position after correction by the distortion vector to a corresponding reference outline position exceeds a determination threshold.

9. A pattern inspection method comprising:
acquiring an inspection image of a substrate on which a figure pattern is formed;
calculating, using a plurality of actual image outline positions on an actual image outline of the figure pattern in the inspection image and a plurality of reference outline positions to be compared with the plurality of actual image outline positions, an average shift vector weighted in a predetermined direction with respect to the actual image outline for performing, by a parallel shift, an alignment between the plurality of actual image outline positions and the plurality of reference outline positions; and
comparing, using the average shift vector, the actual image outline with a reference outline, and outputting a result.

10. The pattern inspection method according to claim 9, wherein, in the comparing the actual image outline with the reference outline, it is determined to be a defect in a case where a magnitude of a defective positional deviation vector according to the average shift vector between each of the plurality of actual image outline positions and its corresponding reference outline position exceeds a determination threshold.
